(19) United States
(12) Patent Application Publication
(10) Pub. No.: US 2025/0262850 A1
(43) Pub. Date: Aug. 21, 2025

(54) CURING DEVICE AND METHOD OF MANUFACTURING DISPLAY DEVICE

(71) Applicant: Samsung Display Co., LTD., Yongin-si (KR)

(72) Inventors: SEUL-GI KIM, Yongin-si (KR); WONJOON CHOI, Yongin-si (KR)

(21) Appl. No.: 19/018,609

(22) Filed: Jan. 13, 2025

(30) Foreign Application Priority Data
Feb. 20, 2024 (KR) 10-2024-0023914

(51) Int. Cl. B32B 38/00

(52) U.S. Cl. CPC B32B 38/00; B32B 2038/0076; B32B 2457/20

(57) ABSTRACT

A curing device includes a support frame including a substrate standby position, a substrate curing position, and a substrate unloading position, a support unit on the support frame, and including a support parts spaced apart from each other in a first direction or a second direction, and while each supporting a bottom surface of a substrates, and a curing unit movable in the first direction, and curing, at a position corresponding to the substrate curing position, the substrate on a support part at the substrate curing position. The curing unit includes a first curing part which when viewed in the second direction, overlaps a top surface of the substrate at the substrate curing position when the curing unit is at a position corresponding to the substrate curing position, and a second curing part, and each of the support parts is movable in the first direction or the second direction.

This application claims priority to Korean Patent Application No. 10-2024-0023914, filed on Feb. 20, 2024, and all the benefits accruing therefrom under 35 U.S.C. § 119, the content of which in its entirety is herein incorporated by reference.

### BACKGROUND

### 1. Field

Embodiments of the disclosure herein relate to a curing device and a method of manufacturing a display device, and more particularly, to a curing device for curing a display module and a method of manufacturing a display device.

### 2. Description of the Related Art

Various display devices used for multimedia devices such as televisions, mobile phones, tablet computers, navigation systems, game consoles, or the like have been developed. Such display devices may include a plurality of electronic components, and may be provided in various shapes and sizes depending on a design.

A display panel may be manufactured variously according to various design conditions. Accordingly, it is desired for a display device manufacturing apparatus to have versatility so that the display device manufacturing apparatus may be used for manufacturing display devices having various specifications in accordance with such various design conditions.

### SUMMARY

Embodiments of the disclosure provide a curing device capable of simultaneously curing a plurality of objects to be cured, and a method of manufacturing a display device.

Embodiments of the disclosure also provide a curing device capable of simultaneously loading and unloading a plurality of objects to be cured, and a method of manufacturing a display device.

Embodiments of the disclosure also provides a curing device capable of simultaneously curing top surfaces and side surfaces of a plurality of objects to be cured, and a method of manufacturing a display device.

An embodiment of the invention provides a curing device including: a support frame including a substrate standby position, a substrate curing position, and a substrate unloading position; a support unit disposed on the support frame, where the support unit includes a plurality of support parts spaced apart from each other in a first direction or a second direction crossing the first direction, and each of the plurality of support parts supports a bottom surface of a corresponding one of a plurality of substrates; and a curing unit movable in the first direction, where the curing unit cures corresponding substrates, among the plurality of substrates, on at least two of the plurality of support parts disposed at the substrate curing position when the curing unit is at a position corresponding to the substrate curing position, where the curing unit includes a first curing part which when viewed in the second direction, overlaps top surfaces of the corresponding substrates and the at least two of the plurality of support parts at the substrate curing position when the curing unit is at the position corresponding to the substrate curing position, and a second curing part spaced apart from the first curing part in the second direction, and each of the plurality of support parts is movable in the first direction or the second direction.

In an embodiment, when viewed in a third direction crossing the first direction and the second direction, the substrate standby position and the substrate unloading position may be spaced apart from the curing unit with the substrate curing position therebetween, the plurality of support parts may include a first support part disposed at the substrate standby position, second support parts disposed at the substrate curing position, and a third support part disposed at the substrate unloading position, and the curing unit may cure the corresponding substrates on the second support parts.

In an embodiment, the second support parts may be arranged in the second direction, and the first curing part and the second curing part may be arranged in the second direction. In an embodiment, when viewed in the second direction and the curing unit is at the position corresponding to the substrate curing position, the second curing part may overlap the top surfaces of the plurality of the substrates and the plurality of the support parts at a position corresponding to the substrate curing position.

the second support parts.

In an embodiment, when viewed in the first direction and the curing unit is at the position corresponding to the substrate curing position, the second curing part may overlap a side surface of a substrate on a corresponding one of the second support parts.

In an embodiment, the curing unit may further include a third curing part spaced apart from the first curing part with the second curing part therebetween, and when viewed in the first direction and the curing unit is at the position corresponding to the substrate curing position, the third curing part may overlap a side surface of a substrate on a corresponding one of the second support parts.

In an embodiment, the support unit may further include a first rotating member extending from the support frame in a third direction crossing the first direction and the second direction and a second rotating member disposed on the first rotating member, where the second rotating member may rotate the second support parts about a direction parallel to the second direction.

In an embodiment, at least one support part among the plurality of support parts may be disposed between the first curing part and the second curing part when the curing unit is at the position corresponding to the substrate curing position.

In an embodiment, when viewed in the second direction, an area of the first curing part may be greater than an area of the plurality of a top surface of each of the plurality of substrates.

In an embodiment, when viewed in the first direction, an area of the second curing part may be greater than an area of a first side surface or a second side surface of each of the plurality of substrates.

In an embodiment of the invention, a curing device includes: a support frame including a substrate standby position, a substrate curing position, and a substrate unloading position; a support unit disposed on the support frame, where the support unit includes a plurality of support parts spaced apart from each other in a first direction or a second direction crossing the first direction, each of the plurality of support parts supports a bottom surface of a corresponding one of a plurality of substrates; and a curing unit movable in the first direction, where the curing unit cures corresponding substrates on at least two of the plurality of support parts disposed at the substrate curing position, when the curing unit is at a position corresponding to the substrate curing position, where the curing unit includes a first curing part which, when viewed in the second direction, overlaps top surfaces of the corresponding substrates when the curing unit is at the position corresponding to the substrate curing position, and a second curing part spaced apart from the first curing part, and overlapping, when viewed in the first direction, a side surface of a substrate of the corresponding substrates when the curing unit is at the position corresponding to the substrate curing position.

In an embodiment, when viewed in a third direction crossing the first direction and the second direction, the substrate standby position and the substrate unloading position may be spaced more apart from the curing unit, than the substrate curing position, the plurality of support parts may include a first support part disposed at the substrate standby position, second support parts disposed at the substrate curing position, and a third support part disposed at the substrate unloading position, and the curing unit may cure the corresponding substrates on the second support parts.

In an embodiment, the curing unit may further include a third curing part spaced apart from the first curing part with the second curing part therebetween, and when viewed in the first direction, the third curing part may overlap a side surface of a substrate among the corresponding substrates when the curing unit is at the position corresponding to the substrate curing position.

In an embodiment, the support unit may further include a first rotating member extending from the support frame in a third direction crossing the first direction and the second direction, and a second rotating member disposed on the first rotating member, where the second rotating member may rotate the plurality of support parts about a direction parallel to the second direction.

In an embodiment, the plurality of support parts may move while rotating about the second direction, as a rotation axis.

In an embodiment of the invention, a method of manufacturing a display device includes: preparing a support unit having a plurality of support parts disposed at a substrate standby position, a substrate curing position, and a substrate unloading position, and a curing unit spaced apart from the support unit and having a plurality of curing parts; loading a substrate on a support part disposed at the substrate standby position among the plurality of support parts; unloading a substrate on a support part disposed at the substrate unloading position among the plurality of support parts; circulating the plurality of support parts in a way such that the support part disposed at the substrate standby position moves to the substrate curing position, one support part a disposed at the substrate curing position among the plurality of support parts moves to the substrate unloading position, and another support part disposed at the substrate unloading position among the plurality of support parts moves to the substrate standby position; performing a first movement such that the curing unit moves to a position corresponding to the substrate curing position; curing the substrate located at the substrate curing position; and performing a second movement in a way such that the curing unit is spaced apart from the position corresponding to the substrate curing position, where the loading the substrate, the unloading the substrate, the circulating the support part, the performing the first movement, the curing the substrate, and the performing the second movement are repeated.

In an embodiment, the substrate curing position may be located between the substrate standby position and the curing unit, and the substrate unloading position may be spaced apart from the curing unit with the substrate curing position therebetween.

In an embodiment, at least two of the plurality of support parts may be disposed at the substrate curing position, in the circulating the support part, one support part among the at least two of the plurality of support parts disposed inside the substrate curing position may move to the substrate unloading position, and another support part among the at least two of the plurality of support parts disposed inside the substrate curing position may each move to a position adjacent to the substrate unloading position, inside the substrate curing position.

In an embodiment, the substrate curing position may include a first curing position, and a second curing position spaced apart from the first curing position, the curing unit may include a first curing part which cures an upper part of the substrate, and a second curing part which cures a side part of the substrate, in the circulating the support part, a support part disposed at the first curing position may move to the second curing position, in the performing the first movement, the first curing part may move to a position corresponding to the first curing position, and the second curing part may move to a position corresponding to the second curing position, and in the curing the substrate, the first curing part may face the upper part of the substrate when the substrate is located at the first curing position, and the second curing part may face the side part of the substrate when the substrate is located at the second curing position.

In an embodiment, the substrate curing position may further include a third curing position spaced apart from the second curing position, the curing unit may further include a third curing part spaced apart from the second curing part wherein the third curing part may cure another side part of the substrate, in the performing the first movement, the third curing part may move to a position corresponding to the third curing position, when the substrate moves from the second curing position to the third curing position, the substrate may rotate about a normal direction of the plurality of support parts, and in the performing the first movement, the third curing part may move to a position corresponding to the third curing position.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view of a display device according to an embodiment of the invention;

FIG. 2 is an exploded perspective view of a display device according to an embodiment of the invention;

FIG. 3 is a cross-sectional view of a display device according to an embodiment of the invention;

FIGS. 4A and 4B are perspective views of a curing device according to an embodiment of the invention;

FIG. 5A is a side view of a curing device according to an embodiment of the invention;

FIG. 5B is a plan view of a curing device according to an embodiment of the invention;

FIGS. 6A and 6B are enlarged views of a support part according to an embodiment of the invention;

FIGS. 7A and 7B are perspective views of a curing device according to an embodiment of the invention;

FIGS. 8A to 8J are perspective views illustrating some processes of a method of manufacturing a display device according to an embodiment of the invention; and

FIGS. 9A and 9B are side views illustrating some processes of a method of manufacturing a display device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or region, layer, portion, etc.) is referred to as being “on”, “connected to” or “coupled to” another element or layer, it can be directly disposed on/connected to/coupled to the other element or intervening elements may be present therebetween. In contrast, when an element is referred to as being “directly on” another element, there are no intervening elements present.

Like reference numerals or symbols refer to like elements throughout the specification. In addition, in terms of drawings, the thickness and the ratio and the dimension of the element are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display panel according to an embodiment of the invention and a method of manufacturing the same will be described with reference to the accompanying drawings.

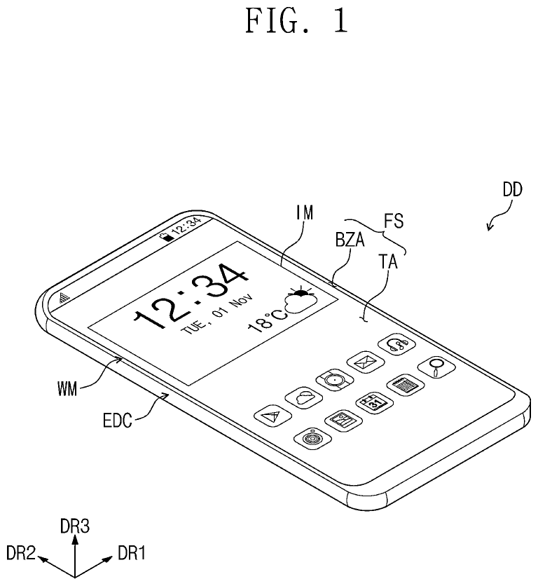

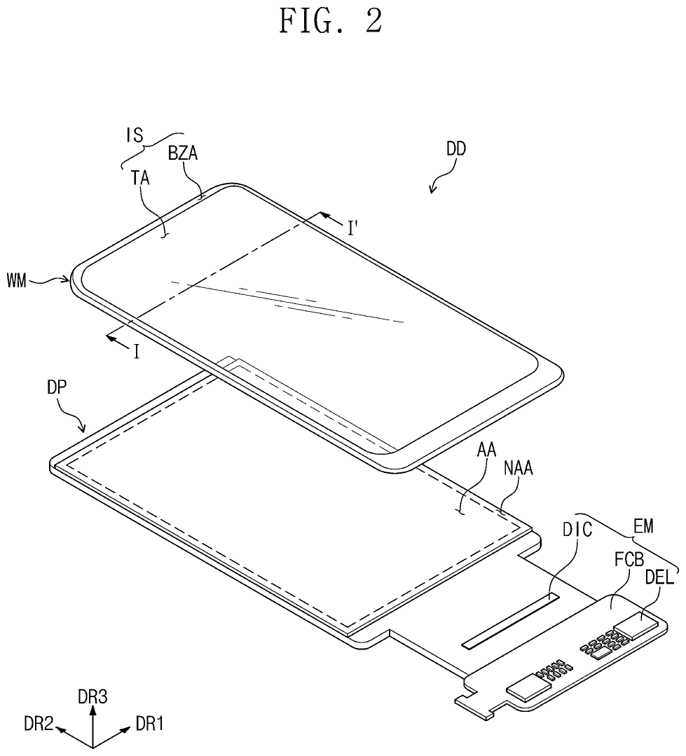

FIG. 1 is a perspective view of a display device according to an embodiment of the invention, and FIG. 2 is an exploded perspective view of a display device according to an embodiment of the invention.

Referring to FIGS. 1 and 2, an embodiment of a display device DD may be activated in response to an electrical signal. The display device DD may be one of various types of display device. In an embodiment, for example, the display device DD may be an electronic device such as a smart watch, a tablet computer, a notebook computer, a computer, a smart television, etc.

The display device DD may display, in a third direction DR3, an image IM on a display surface IS parallel to each of a first direction DR1 and a second direction DR2 (or on a plane defined by the first direction DR1 and the second direction DR2). Here, the third direction DR3 may be a thickness direction of the display device DD. The display surface IS on which the image IM is displayed may correspond to a front surface of the display device DD. The image IM may include a static image as well as a dynamic image.

In such an embodiment, a front surface (or top surface) and a rear surface (or bottom surface) of each of members may be defined on the basis of the third direction DR3 in which the image IM is displayed. The front surface and the rear surface may be opposed to each other in the third direction DR3, and normal directions of the front surface and the rear surface may each be parallel to the third direction DR3.

A spaced distance between the front surface and the rear surface in the third direction DR3 may correspond to a thickness of an electronic device in the third direction DR3. Here, directions indicated by the first to third directions DR1, DR2, and DR3 may have a relative concept and may thus be changed to other directions.

In an embodiment, the display device DD may sense a user's input applied from the outside. The user's input may include various types of external inputs such as a part of the user's body, light, heat, pressure, or the like. In addition, the display device DD may sense an input close to or adjacent to the display device DD as well as an input touching the display device DD.

In addition, the display device DD may sense the user's input applied to a side surface or a rear surface of the display device DD depending on a structure of the display device DD, and the invention is not limited to any one embodiment.

The front surface of the display device DD may be divided into a transmission region TA and a bezel region BZA. The transmission region TA may be a region in which the image IM is displayed. A user may view the image IM through the transmission region TA. In an embodiment, as shown in FIG. 1, the transmission region TA may be in a quadrangular shape having rounded corners. However, this is illustrated as an example, and the transmission region TA may have various shapes and is not limited to any one embodiment.

The bezel region BZA may be adjacent to the transmission region TA. The bezel region BZA may have a predetermined color. The bezel region BZA may surround the transmission region TA. Accordingly, a shape of the transmission region TA may be substantially defined by the bezel region BZA. However, this is illustrated as an example, and in another embodiment, the bezel region BZA may be disposed adjacent to only one side of the transmission region TA, or may be omitted. The display device DD according to an embodiment of the invention may be variously modified, and is not limited to any one embodiment.

In an embodiment, as shown in FIG. 2, the display device DD may include a window WM, a display module, and a drive module EM.

The window WM may include or be composed of a transparent substance to output an image. In an embodiment, for example, the window WM may include or be composed of glass, sapphire, plastic, or the like. For convenience of illustration, the window WM is illustrated as a single layer in FIG. 2, but is not limited thereto. The window WM may include multiple layers. In an embodiment, although not illustrated, the bezel region BZA of the aforementioned display device DD may be substantially provided as a region in which a substance having a predetermined color is printed onto one region of the window WM.

The display module may include a display panel DP and an input sensing layer. The display panel DP according to an embodiment of the invention may be an emissive display panel, but is not particularly limited thereto. In an embodiment, for example, the display panel DP may be an organic light-emitting display panel, an inorganic light-emitting display panel, or a quantum dot light-emitting display panel. A light-emitting layer of the organic light-emitting display panel may include an organic light-emitting substance, and a light-emitting layer of the inorganic light-emitting display panel may include an inorganic light-emitting substance. A light-emitting layer of the quantum dot light-emitting display panel may include quantum dots, quantum rods, and the like. Hereinafter, the display panel DP will be described as an organic light-emitting display panel.

The input sensing layer may be disposed directly on the display panel DP. According to an embodiment of the invention, the input sensing layer may be formed on the display panel DP through a continuous process.

The display panel DP may generate the image IM, and the input sensing layer may acquire coordinate information about an external input (for example, a touch event).

In an embodiment, although not illustrated, the display device DD may further include an additional layer, for example, an optical layer or functional layers, disposed between the display panel DP and the window WM.

In an embodiment, the display panel DP may display the image IM and sense an external input. That is, the display panel DP may display an image in response to an electrical signal, and transmit/receive information about the external input. The display panel DP may be defined as an active region AA and a peripheral region NAA. In such an embodiment, the active region AA may be a region in which the image IM is displayed and an external input is sensed, as well. However, this is illustrated as an example, and within the active region AA, a region in which the image IM is displayed and a region in which an external input is sensed may be separated from each other. The invention is not limited to any one embodiment.

The peripheral region NAA is adjacent to the active region AA. In an embodiment, for example, the peripheral region NAA may surround the active region AA. However, this is illustrated as an example, and the peripheral region NAA may be defined as having various shapes, and is not limited to any one embodiment. According to an embodiment, the active region AA of the display panel DP may correspond to at least a portion of the transmission region TA.

Various signal lines or pads for providing an electrical signal to the active region AA, electronic elements or the like may be disposed in the peripheral region NAA. The peripheral region NAA may be covered by the bezel region BZA and may not be viewed from the outside.

The drive module EM may control an operation of the display panel DP. The drive module EM may include a flexible circuit film FCB and a driving chip DIC. The flexible circuit film FCB may be electrically connected to the display panel DP. The flexible circuit film FCB may be coupled to an end of the display panel DP through a bonding process. The flexible circuit film FCB may be electrically connected to the display panel DP through an anisotropic conductive adhesive layer. The driving chip DIC may be mounted on the display panel DP. The driving chip DIC may include driving circuits, for example a data driving circuit, for driving a pixel of the display panel DP.

The drive module EM may further include a plurality of driving elements DEL mounted on the flexible circuit film FCB. The plurality of driving elements DEL may include a circuit unit for converting a signal input from the outside into a signal required for the driving chip DIC, or into a signal required to drive the display panel DP.

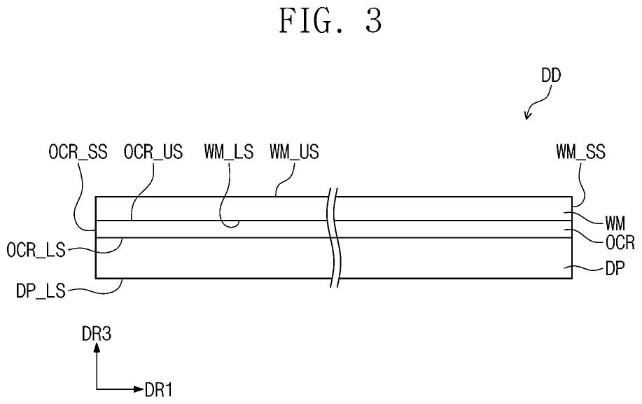

FIG. 3 is a cross-sectional view of a display device according to an embodiment of the invention.

Referring to FIG. 3, a display device DD according to an embodiment of the invention may include a display panel DP, an adhesive member OCR, and a window WM. The adhesive member OCR may be disposed between the display panel DP and the window WM, and may couple the window WM and the display panel DP to each other.

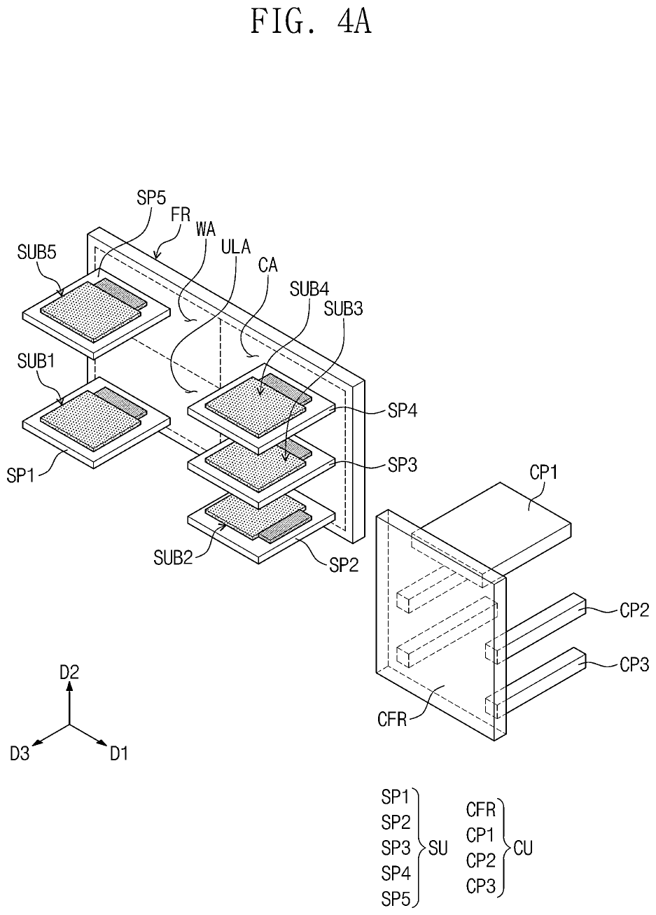

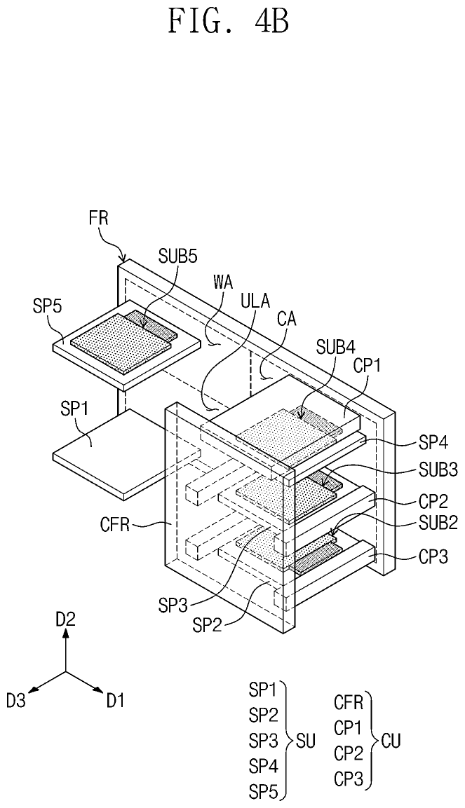

A curing unit CU (see FIG. 4A) of a curing device to be described later may cure a top surface OCR_US, a side surface OCR_SS, and a bottom surface OCR_LS of the adhesive member OCR. Since the top surface OCR_US, the side surface OCR_SS, and the bottom surface OCR_LS of the adhesive member OCR are cured, a uniform curing quality may be achieved. In addition, the curing unit CU (see FIG. 4A) may also cure a top surface WM_US, a side surface WM_SS, and a bottom surface WM_LS of the window WM.

Without being limited to what is illustrated in the drawing, the window WM may be disposed directly on a top surface DP-US of the display panel DP, and is not limited to any one embodiment.

FIGS. 4A and 4B are perspective views of a curing device according to an embodiment of the invention.

First to third directions D1, D2, and D3 illustrated in FIG. 4A may indicate directions different from the first to third directions DR1, DR2, and DR3 illustrated above in FIGS. 1 and 2.

Referring to FIG. 4A, an embodiment of a curing device may include a support frame FR, a support unit SU, and a curing unit CU.

The support frame FR may include a surface on a plane defined by the second direction D2 and the third direction D3 crossing the second direction D2. In an embodiment, as shown in FIG. 4A, the support frame FR may have a rectangular shape, but the shape of the support frame FR is not limited thereto, and may have various shapes.

The support frame FR may include a substrate standby position (or area) WA, a substrate curing position CA, and a substrate unloading position ULA. On a plane or when viewed in the first direction D1, the substrate standby position WA and the substrate unloading position ULA may be spaced apart from the curing unit CU in the second direction D2 with the substrate curing position CA therebetween. The substrate unloading position ULA may be disposed under the substrate standby position WA, and the substrate curing position CA may be disposed at one side of the substrate standby position WA and at one side of the substrate unloading position ULA.

At the substrate standby position WA, a substrate SUB5 before being cured may be loaded on support parts SP1, SP2, SP3, SP4, and SP5 to be described later. At the substrate curing position CA, substrates SUB2, SUB3, and SUB4 may be cured, and at the substrate unloading position ULA, a cured substrate SUB1 may be unloaded. Here, a substrate or a support may be considered as being at a specific position of the support frame FR when the substrate or the support is disposed to overlap the specific position in the first direction D1.

The substrate SUB5 before being cured described herein may be a preliminary display device that is the aforementioned display device DD (see FIG. 3) including the adhesive member OCR (see FIG. 3) which is not cured yet. However, without being limited thereto, the substrate SUB5 before being cured may be a preliminary display device that is the aforementioned display device DD (see FIG. 3) including the window WM (see FIG. 3) which is not cured yet, and the invention is not limited to any one embodiment.

The support unit SU may include the support parts SP1, SP2, SP3, SP4, and SP5. A substrate may be disposed on the support parts SP1, SP2, SP3, SP4, and SP5, and the support parts SP1, SP2, SP3, SP4, and SP5 may support a bottom surface of the substrate. The support parts SP1, SP2, SP3, SP4, and SP5 may move in the second direction D2 or in a direction crossing the second direction D2. In an embodiment, for example, the support parts SP1, SP2, SP3, SP4, and SP5 may move in the second direction D2 or in the third direction D3. The substrate on the support parts SP1, SP2, SP3, SP4, and SP5 may rotate about the third direction D3 (i.e., rotate about a rotational axis in the third direction D3).

The support parts SP1, SP2, SP3, SP4, and SP5 may be provided in plurality. The plurality of support parts SP1, SP2, SP3, SP4, and SP5 may be spaced apart from each other in the second direction D2 or in the direction crossing the second direction D2. Referring to the drawing, the plurality of support parts SP1, SP2, SP3, SP4, and SP5 may be spaced apart from each other in the second direction D2 or in the third direction D3. The substrates SUB1, SUB2, SUB3, SUB4, and SUB5 may be respectively disposed on the support parts SP1, SP2, SP3, SP4, and SP5.

Among the plurality of support parts SP1, SP2, SP3, SP4, and SP5, a support part SP5 disposed at the substrate standby position WA may be defined as a first support part SP5, support parts SP2, SP3, and SP4 disposed at the substrate curing position CA may be defined as second support parts SP2, SP3, and SP4, and a support part SP1 disposed at the substrate unloading position may be defined as a third support part SP1. Since the support parts SP1, SP2, SP3, SP4, and SP5 move along the first direction D1 or a direction crossing thereover, the support parts SP1, SP2, SP3, SP4, and SP5, which are defined as the first to third support parts SP1, SP2, SP3, SP4, and SP5, may be changed, and the reference numerals or symbols of the first to third support parts SP1, SP2, SP3, SP4, and SP5 may be the same as or different from each other.

The second support parts SP2, SP3, and SP4 may be spaced apart from the first support part SP5 in the second direction D2. The third support part SP1 may be spaced apart from the second support parts SP2, SP3, and SP4 in the second direction D2. The third support part SP1 may be spaced apart from the first support part SP5 in the third direction D3.

The second support parts SP2, SP3, and SP4 may be provided in plurality. The second support parts SP2, SP3, and SP4 may be arranged in the third direction D3.

The curing unit CU may move forward and backward in the second direction D2. The curing unit CU may overlap or may not overlap the support frame FR. In an embodiment, the curing unit CU may move to overlap the support frame FR, and cure the substrates SUB2, SUB3, and SUB4 located at the substrate curing position CA.

The curing unit CU may include curing parts CP1, CP2, and CP3. The curing parts CP1, CP2, and CP3 may cure a substrate, e.g., a layer or portion thereof to be cured. The layer or portion of the substrate to be cured may be a curable material layer or portion included or previously formed in the substrate. The curing parts CP1, CP2, and CP3 may be provided in plurality. The plurality of curing parts CP1, CP2, and CP3 may each cure a top surface or a side surface of the substrate. The plurality of curing parts CP1, CP2, and CP3 may include top-surface curing parts for curing the top surface of the substrate, or side-surface curing parts for curing the side surface of the substrate.

The curing parts CP1, CP2, and CP3 may include a first curing part CP1, a second curing part CP2, and a third curing part CP3. The second curing part CP2 may be spaced apart from the first curing part CP1 in the third direction D3. The third curing part CP3 may be spaced apart from the first curing part CP1 in the third direction D3 with the second curing part CP2 therebetween.

Referring to FIG. 4B, the curing unit CU may move to a position corresponding to the substrate curing position CA. When the curing unit CU moves to the position corresponding to the substrate curing position CA, the curing unit CU may cure the substrates SUB2, SUB3, and SUB4 located at the substrate curing position CA.

The first curing part CP1 may include a top-surface curing part. When the curing unit CU is located at the position corresponding to the substrate curing position CA, the first curing part CP1 may overlap top surfaces of the substrates SUB2, SUB3, and SUB4 and some of the support parts SP2, SP3, and SP4 when viewed in the third direction D3.

The second curing part CP2 may include a side-surface curing part. The third curing part CP3 may include a side-surface curing part. In an embodiment, as illustrated in FIG. 4B, the second curing part CP2 and the third curing part CP3 may each include the side-surface curing part, but an embodiment of the invention is not limited thereto. In another embodiment, the second curing part CP2 and the third curing part CP3 may each include the top-surface curing part like the first curing part CP1, and the invention is not limited to any one embodiment.

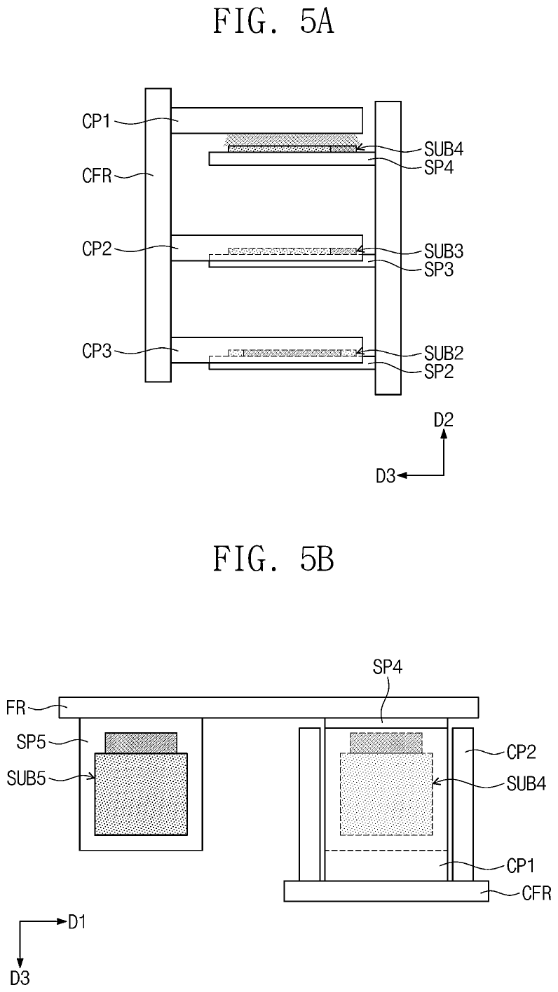

FIG. 5A is a side view of a curing device according to an embodiment of the invention, and FIG. 5B is a plan view of a curing device according to an embodiment of the invention.

Referring to FIG. 5A, in an embodiment, a first curing part CP1 may be spaced apart from a top surface of a substrate SUB4 by a predetermined distance. The first curing part CP1 is spaced apart from the top surface of the substrate SUB4 by the predetermined distance, such that the first curing part CP1 may be effectively prevented from contacting the top surface of the substrate SUB4. Thus, in such an embodiment, damage to the substrate SUB4 may be effectively prevented.

When a curing unit CU is located at a position corresponding to a substrate curing position CA, at least one support part SP2 among second support parts SP2, SP3, and SP4 may be located between the first curing part and a second curing part.

When the curing unit CU is located at a position corresponding to the substrate curing position CA, the second curing part CP2 may overlap a side surface of a substrate SUB3 and a portion of the support part SP3 when viewed in a second direction D2. In addition, when viewed in the second direction D2, an area of the second curing part CP2 may be greater than an area of one side surface of the substrate SUB3.

When the curing unit CU is located at a position corresponding to the substrate curing position CA, a third curing part CP3 may overlap a side surface of a substrate SUB2 and a portion of the support part SP2 when viewed in the second direction D2. In addition, when viewed in the second direction D2, an area of the third curing part CP3 may be greater than an area of one side surface of the substrate SUB2.

Therefore, the second curing part CP2 and the third curing part CP3 may uniformly cure the side surfaces of the substrates SUB2 and SUB3.

Referring to FIG. 5B, on a plane or when viewed in the third direction D3, an area of the first curing part CP1 may be greater than an area of the top surface of the substrate SUB4. Accordingly, the first curing part CP1 may cure the entire top surface of the substrate SUB4 all at once.

The second curing part CP2 may be spaced apart from the side surface of the substrate SUB3 (see FIG. 5A) by a predetermined distance. That is, the second curing part CP2 may not overlap the substrate SUB3 (see FIG. 5A) on a plane or when viewed in the third direction D3. The second curing part CP2 is spaced apart from the side surface of the substrate SUB3 (see FIG. 5A) by the predetermined distance, such that the second curing part CP2 may be effectively prevented from contacting the side surface of the substrate SUB3 (see FIG. 5A). Thus, in such an embodiment, damage to the substrate may be effectively prevented.

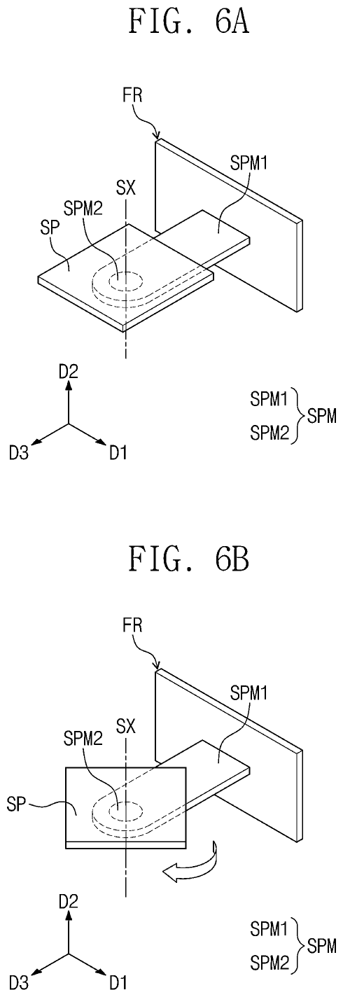

FIGS. 6A and 6B are enlarged views of the support parts SP1, SP2, SP3, SP4, and SP5 (see FIG. 4A) according to an embodiment of the invention.

Referring to FIGS. 6A and 6B, in an embodiment, the support unit SU (see FIG. 4A) may further include a plurality of rotating members SPM. The plurality of rotating members SPM may be respectively coupled to the support parts SP1, SP2, SP3, SP4, and SP5 (see FIG. 4A).

The plurality of rotating members SPM may each include a first rotating member SPM1 and a second rotating member SPM2. The first rotating member SPM1 may extend from a support frame FR in a first direction D1. The second rotating member SPM2 may be provided on the first rotating member SPM1, and may rotate the support parts SP1, SP2, SP3, SP4, and SP5 (see FIG. 4A) about a direction crossing the first direction D1. Referring to the drawing, the second rotating member SPM2 may rotate the support parts SP1, SP2, SP3, SP4, and SP5 (see FIG. 4A) about a direction parallel to a third direction D3. The first rotating member SPM1 and the second rotating member SPM2 are capable of rotating the support parts SP1, SP2, SP3, SP4, and SP5 (see FIG. 4A) in a way, such that all the side surfaces of a substrate may face a side-surface curing part, and may be cured while facing the side-surface curing part. Accordingly, the curing quality of the side surfaces of the substrates may be made substantially uniform.

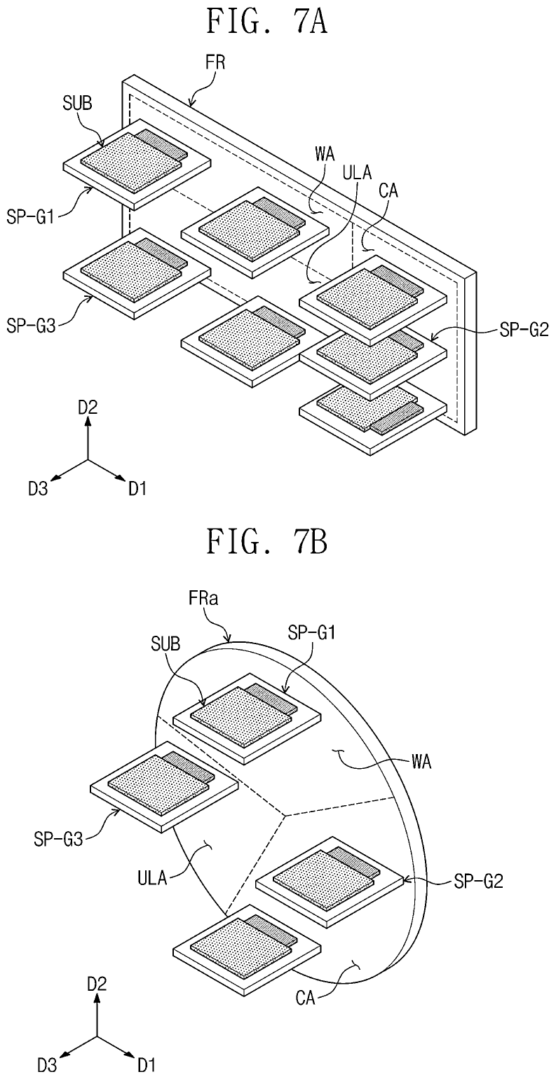

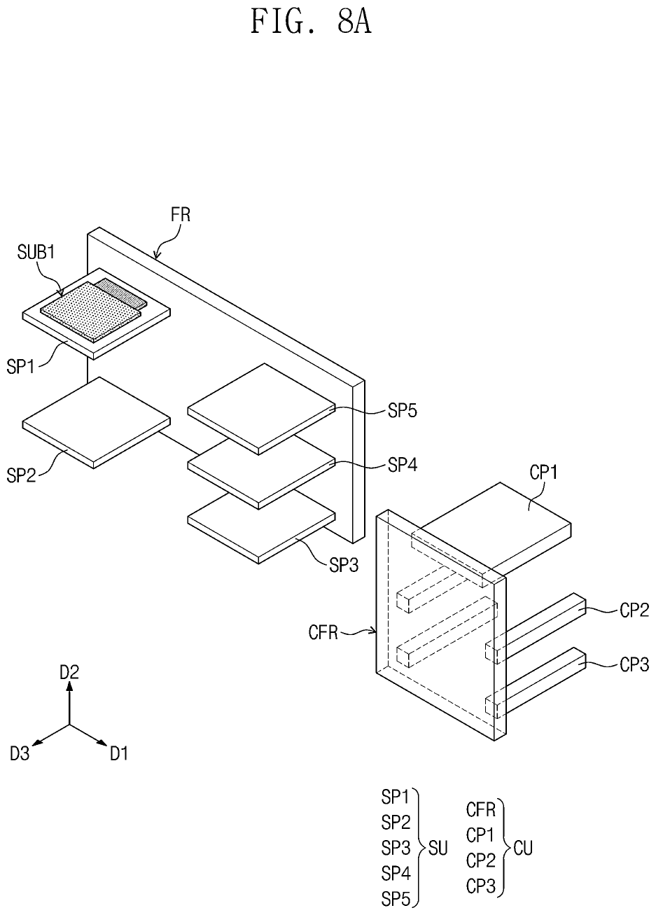

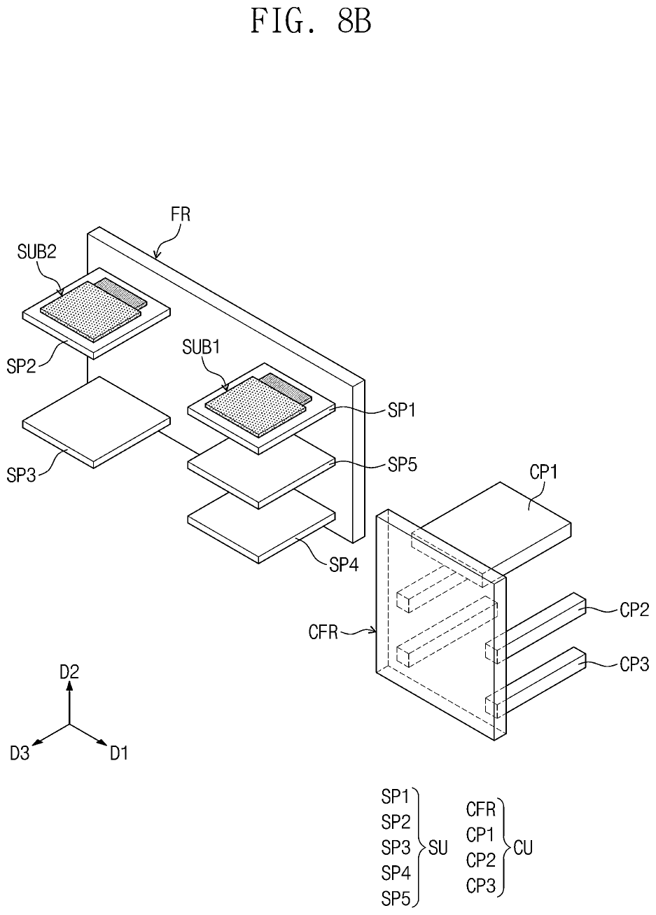

FIGS. 7A and 7B are perspective views of a curing device according to an embodiment of the invention. FIG. 7A and FIG. 7B each illustrate another embodiment of a curing device according the invention which is illustrated in FIG. 4A.

Referring to FIG. 7A, in an embodiment, at a substrate standby position WA, a plurality of first support parts SP-G1 may be provided. In addition, at a substrate unloading position ULA, a plurality of third support parts SP-G3 may be provided. Accordingly, substrates may be simultaneously loaded on and unloaded from the plurality of support parts SP-G1, SP-G2, and SP-G3, thereby increasing process efficiency.

The plurality of first support parts SP-G1 may be arranged in a second direction D2. In addition, the plurality of third support parts SP-G3 may be arranged in the second direction D2.

Since the support parts SP-G1, SP-G2, and SP-G3 cyclically move, the support parts defined as first to third support parts SP-G1, SP-G2, and SP-G3 may be changed.

Referring to FIG. 7B, in another embodiment, a support frame FRa may be provided in a circular shape. In addition, a substrate standby position WA, a substrate curing position CA, and a substrate unloading position ULA may be provided in a fan shape.

The first to third support parts SP-G1, SP-G2, and SP-G3 may rotate about a first direction D1, and may be disposed at any one position among the substrate standby position WA, the substrate curing position CA, and the substrate unloading position ULA.

A curing unit CU may be provided in various shapes corresponding to shapes of the support frame FR, the substrate standby position WA, the substrate curing position CA, and the substrate unloading position ULA, and the invention is not limited to any one embodiment.

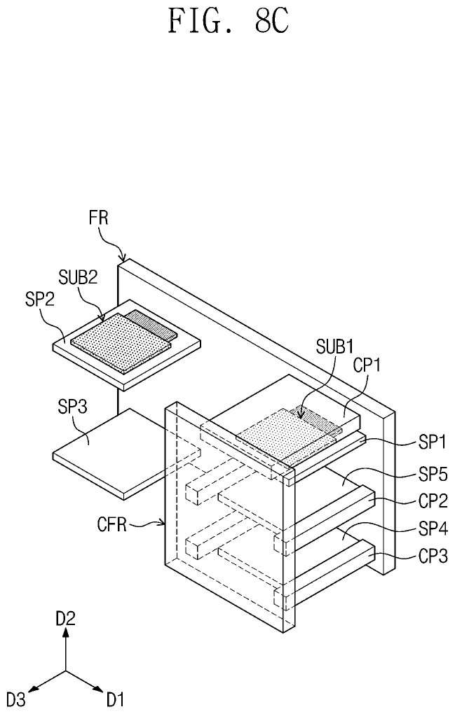

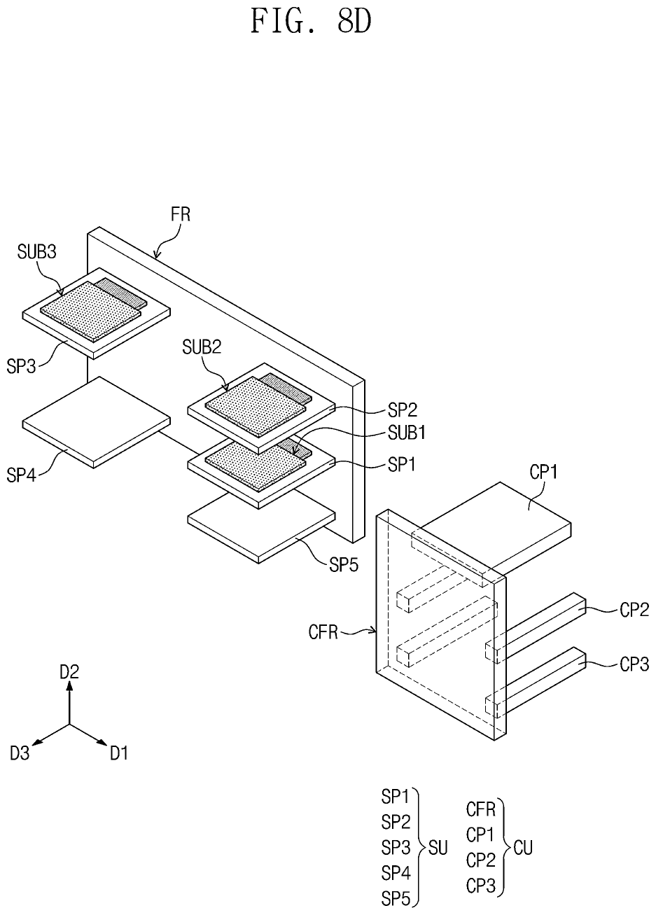

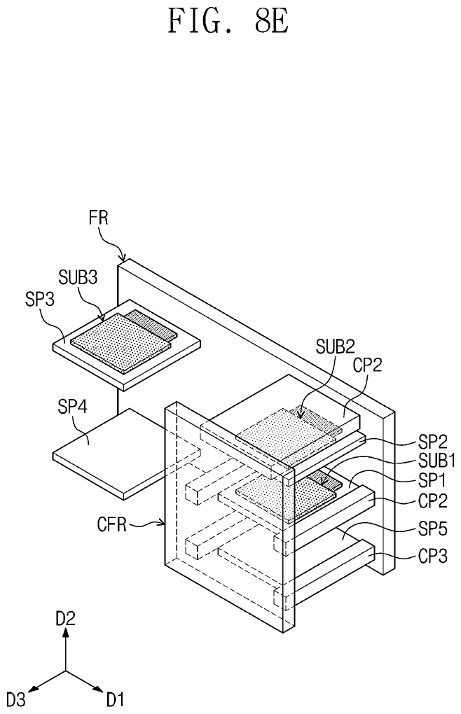

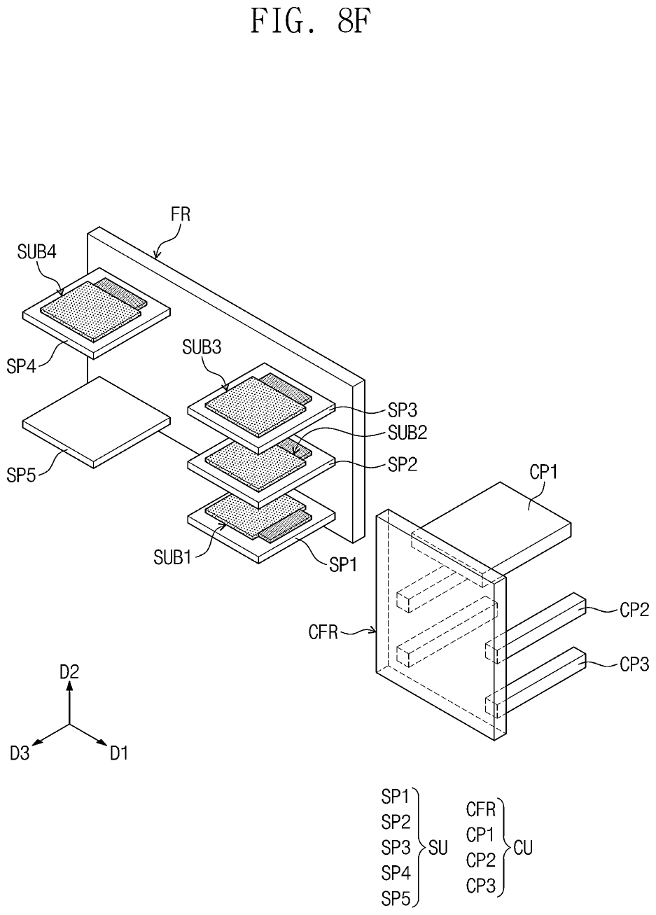

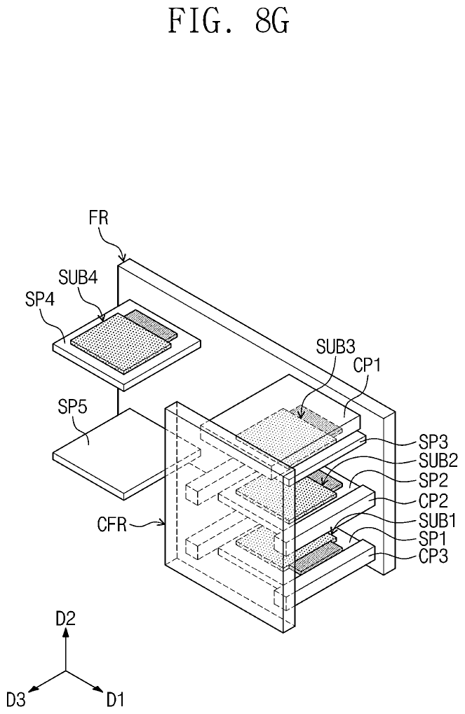

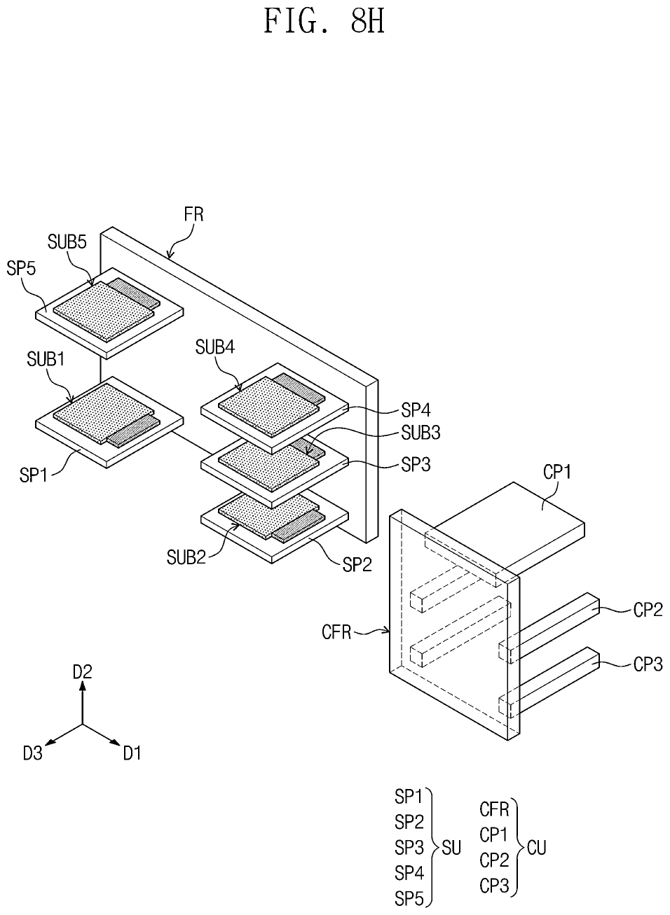

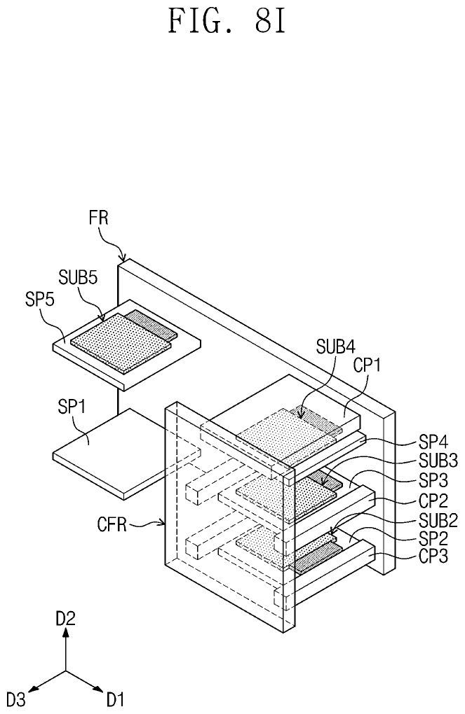

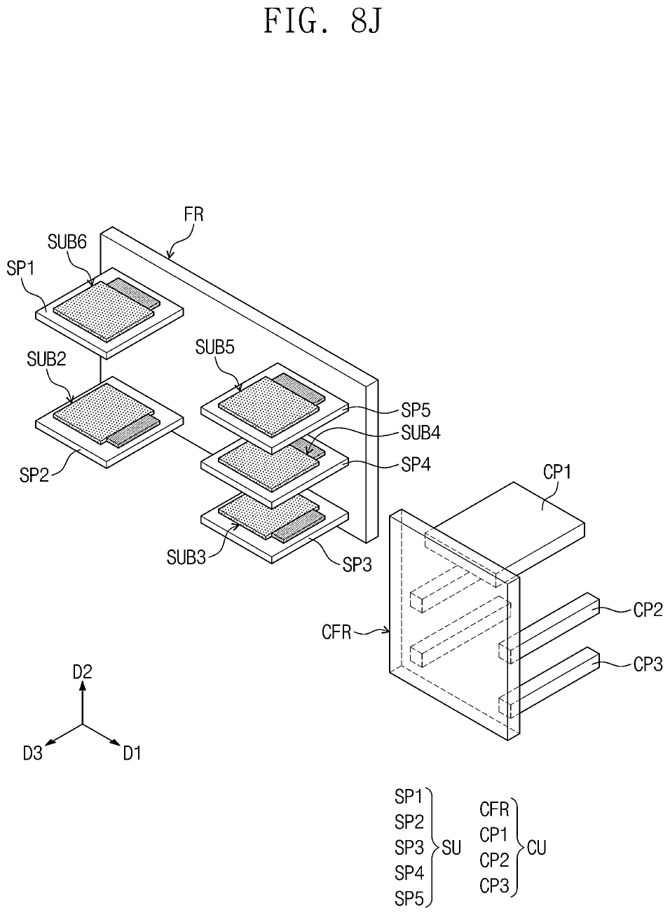

FIGS. 8A to 8J are perspective views illustrating some processes of a method of manufacturing a display device according to an embodiment of the invention.

A method of manufacturing a display device according to an embodiment of the invention may include a process including preparing a support unit having a plurality of support parts disposed at a substrate standby position, a substrate curing position, and a substrate unloading position, and a curing unit spaced apart from the support unit and having a plurality of curing parts, a substrate loading process including loading a substrate on a support part disposed at the substrate standby position, a substrate unloading process including unloading the substrate disposed at the substrate unloading position, a support part circulating process including moving a support part disposed at the substrate standby position to the substrate curing position, moving one support part among support parts disposed at the substrate curing position to the substrate unloading position, and moving a support part disposed at the substrate unloading position to the substrate standby position, a first movement process including moving the curing unit to a position corresponding to the substrate curing position, a substrate curing process of curing substrates located at the substrate curing position, and a second movement process of causing the curing unit to be spaced apart from a position corresponding to the substrate curing position.

According to an embodiment of the invention, the substrate loading process, the substrate unloading process, the support part circulating process, the first movement process, the substrate curing process, and the second movement process may be performed repeatedly.

Referring FIGS. 4A and 8A, a first substrate SUB1 (substrate no. 1) may be loaded on a first support part SP1 (support part no. 1) in a state in which the curing unit CU is spaced apart from the support unit in a second direction D2. The first support part SP1 may be located at a substrate standby position WA. As illustrated in the drawing, a second support part SP2 may be located at a substrate unloading position ULA. However, without being limited thereto, the second support part SP2 may be located at the substrate standby position WA, and the invention is not limited to any one embodiment.

Referring FIGS. 4A and 8B, the first support part SP1 and the first substrate SUB1 may move to the substrate curing position CA. The second support part SP2 may be located at the substrate standby position WA. A second substrate SUB2 may be loaded on the second support part SP2. A third support part SP3 may move from the substrate curing position CA to the substrate unloading position ULA.

Referring to FIGS. 4B and 8C, the curing unit CU may move to a position corresponding to the substrate curing position CA (the first movement process). A top surface of the first substrate SUB1 may be cured by a first curing part CP1.

Referring to FIGS. 4A and 8D, the curing unit CU may be spaced apart from a position corresponding to the substrate curing position CA (the second movement process). The second support part SP2 and the second substrate SUB2 may move to the substrate curing position CA. The third support part SP3 may move to the substrate standby position WA. A third substrate SUB3 may be disposed on the third support part SP3.

The curing part disposed at the substrate curing position CA may move to a position adjacent to the substrate unloading position ULA, inside the substrate curing position CA. In an embodiment, for example, the first support part SP1 and the first substrate SUB1 may move to a position which is more adjacent to the substrate unloading position ULA than the second support part SP2 and the second substrate SUB2. In such an embodiment, the first support part SP1 and the first substrate SUB1 may move from a first curing position, which is adjacent to the substrate standby position WA, to a second curing position, which is adjacent to the substrate unloading position ULA. The second support part SP2 and the second substrate SUB2 may move to the first curing position.

Referring to FIGS. 4B and 8E, the curing unit CU may move to a position corresponding to the substrate curing position CA (the first movement process). The first curing part CP1 may move to a position corresponding to the first curing position, and the second curing part CP2 may move to a position corresponding to the second curing position. A first side surface of the first substrate SUB1 may be cured by the second curing part CP2. A top surface of the second substrate SUB2 may be cured by the first curing part CPL.

Referring to FIGS. 4A and 8F, the curing unit CU may be spaced apart from a position corresponding to the substrate curing position CA (the second movement process). The third support part SP3 and the third substrate SUB3 may move to the substrate curing position CA. The third support part SP3 and the third substrate SUB3 may move to the first curing position. The second support part SP2 and the second substrate SUB2 may move to the second curing position. The first support part SP1 and the first substrate SUB1 may move to a third curing position which is more adjacent to the substrate unloading position ULA than the first curing position. The first substrate SUB1 may rotate 90 degrees about a third direction D3 on the first support part SP1 while the first support part SP1 and the first substrate SUB1 are moving to the third curing position.

A fourth support part SP4 may move to the substrate standby position WA. A fourth substrate SUB4 may be disposed on the fourth support part SP4.

Referring to FIGS. 4B and 8G, the curing unit CU may move to a position corresponding to the substrate curing position CA (the first movement process). The first curing part CP1 may move to a position corresponding to the first curing position, the second curing part CP2 may move to a position corresponding to the second curing position, and the third curing part CP3 may move to a position corresponding to the third curing position. A second side surface of the first substrate SUB1 may be cured by the third curing part CP3. A first side surface of the second substrate SUB2 may be cured by the second curing part CP2. A top surface of the third substrate SUB3 may be cured by the third curing part CP1.

Referring to FIGS. 4A and 8H, the curing unit CU may be spaced apart from a position corresponding to the substrate curing position CA (the second movement process). The fourth support part SP4 and the fourth substrate SUB4 may move to the substrate curing position CA. The fourth support part SP4 and the fourth substrate SUB4 may move to the first curing position. The third support part SP3 and the third substrate SUB3 may move to the second curing position. The second support part SP2 and the second substrate SUB2 may move to the third curing position. The second substrate SUB2 may rotate 90 degrees about the third direction D3 on the second support part SP2 while the second support SP2 and the second substrate SUB2 are moving to the third curing position.

The first support part SP1 and the first substrate SUB1 may move to the substrate unloading position ULA. The first substrate SUB1 which has been cured may be unloaded from the first support part SPL. A fifth support part SP5 may move to the substrate standby position WA. A fifth substrate SUB5 may be disposed on the fifth support part SP5.

A procedure in which the fifth substrate SUB5 is loaded on the fifth support part SP5 and a procedure in which the first substrate SUB1 is unloaded from the first support part SP1 may be performed simultaneously.

Referring to FIGS. 4B and 8I, the curing unit CU may move to a position corresponding to the substrate curing position CA (the first movement process). The first curing part CP1 may move to a position corresponding to the first curing position, the second curing part CP2 may move to a position corresponding to the second curing position, and the third curing part CP3 may move to a position corresponding to the third curing position. A second side surface of the second substrate SUB2 may be cured by the third curing part CP3. A first side surface of the third substrate SUB3 may be cured by the second curing part CP2. A top surface of the fourth substrate SUB4 may be cured by the third curing part CPL.

Referring to FIGS. 4A and 8J, the curing unit CU may be spaced apart from a position corresponding to the substrate curing position CA (the second movement process). The fifth support part SP5 and the fifth substrate SUB5 may move to the substrate curing position CA. The fifth support part SP5 and the fifth substrate SUB5 may move to the first curing position. The fourth support part SP4 and the fourth substrate SUB4 may move to the second curing position. The third support part SP3 and the third substrate SUB3 may move to the third curing position. The third substrate SUB3 may rotate 90 degrees about the third direction D3 on the third support part SP3 while the third support part SP3 and the third substrate SUB3 are moving to the third curing position.

The second support part SP2 and the second substrate SUB2 may move to the substrate unloading position ULA. The second substrate SUB2 which has been cured may be unloaded from the second support part SP2. The first support part SP1 may move to the substrate standby position WA. A sixth substrate SUB6 may be disposed on the first support part SP1.

A procedure in which the sixth substrate SUB6 is loaded on the first support part SP1 and a procedure in which the second substrate SUB2 is unloaded from the second support part SP2 may be performed simultaneously.

Such procedures may be performed continuously and repeatedly.

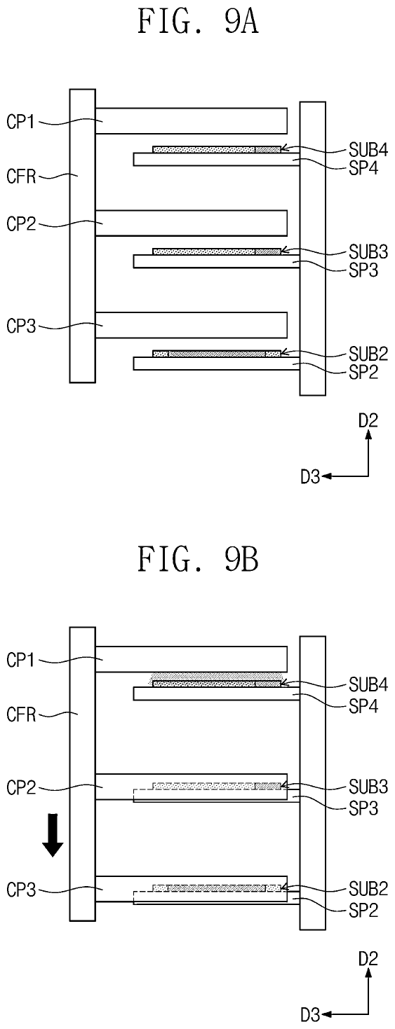

FIGS. 9A and 9B are side views illustrating some processes of a method of manufacturing a display device according to an embodiment of the invention.

FIGS. 9A and 9B illustrate a movement of the curing unit in the third direction after the first movement process and before the curing process, and a movement of the curing unit in the third direction after the curing process and before the second movement process.

In the first movement process, the first to third curing parts CP1, CP2, and CP3 may not overlap the support parts SP2, SP3, and SP4 on a plane defined by a first direction and the third direction. Accordingly, in the first movement process, the first to third curing parts CP1, CP2, and CP3 may be effectively prevented from colliding with the support parts SP2, SP3, and SP4 or the substrates SUB2, SUB3, and SUB4. Thus, damage to the substrates may be effectively prevented.

After the first movement process and before the curing process, the first to third curing parts CP1, CP2, and CP3 may move in the third direction D3. In this case, the second curing part CP2 and the third curing part CP3 may respectively overlap the substrates SUB2 and SUB3 on a plane defined by the first direction D1 and the third direction D3. Accordingly, side surfaces of the substrates may be effectively cured. In addition, since gaps between the curing parts CP1, CP2, and CP3 and the substrates SUB2, SUB3, and SUB4 are adjustable, curing quality may be maintained uniformly by adjusting the gaps as desired.

After the curing process and before the second movement process, the first to third curing parts may move in the third direction D3, and in the second movement process, the first to third curing parts CP1, CP2, and CP3 may be prevented from colliding with the support parts SP2, SP3, and SP4 or the substrates SUB2, SUB3, and SUB4.

A curing device and a method of manufacturing a display device, according to an embodiment of the invention, make it possible to simultaneously cure a plurality of objects to be cured.

A curing device and a method of manufacturing a display device, according to an embodiment of the invention, make it possible to simultaneously load and unload a plurality of objects to be cured.

A curing device and a method of manufacturing a display device, according to an embodiment of the invention, make it possible to simultaneously cure top surfaces and side surfaces of a plurality of objects to be cured.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A curing device comprising:
a support frame including a substrate standby position, a substrate curing position, and a substrate unloading position;
a support unit disposed on the support frame, wherein the support unit includes a plurality of support parts spaced apart from each other in a first direction or a second direction crossing the first direction, and each of the plurality of support parts supports a bottom surface of a corresponding one of a plurality of substrates; and
a curing unit movable in the first direction, wherein the curing unit cures corresponding substrates, among the plurality of substrates, on at least two of the plurality of support parts disposed at the substrate curing position when the curing unit is at a position corresponding to the substrate curing position,
wherein the curing unit includes
a first curing part which, when viewed in the second direction, overlaps top surfaces of the corresponding substrates and the at least two of the plurality of support parts at the substrate curing position when the curing unit is at the position corresponding to the substrate curing position, and
a second curing part spaced apart from the first curing part in the second direction, and
each of the plurality of support parts is movable in the first direction or the second direction.

2. The curing device of claim 1, wherein when viewed in a third direction crossing the first direction and the second direction, the substrate standby position and the substrate unloading position are spaced apart from the curing unit with the substrate curing position therebetween,
the plurality of support parts comprises a first support part disposed at the substrate standby position, second support parts disposed at the substrate curing position, and a third support part disposed at the substrate unloading position, and
the curing unit cures the corresponding substrates on the second support parts.

3. The curing device of claim 2, wherein the second support parts are arranged in the second direction, and the first curing part and the second curing part are arranged in the second direction.

4. The curing device of claim 2, wherein when viewed in the second direction and the curing unit is at the position corresponding to the substrate curing position, the second curing part overlaps the top surfaces of the plurality of the substrates and the plurality of the support parts at a position corresponding to the substrate curing position.

5. The curing device of claim 2, wherein when viewed in the first direction and the curing unit is at the position corresponding to the substrate curing position, the second curing part overlaps a side surface of a substrate on a corresponding one of the second support parts.

6. The curing device of claim 2, wherein the curing unit further comprises a third curing part spaced apart from the first curing part with the second curing part therebetween, and
when viewed in the first direction and the curing unit is at the position corresponding to the substrate curing position, the third curing part overlaps a side surface of a substrate on a corresponding one of the second support parts.

7. The curing device of claim 6, wherein the support unit further comprises:
a first rotating member extending from the support frame in a third direction crossing the first direction and the second direction; and
a second rotating member disposed on the first rotating member, wherein the second rotating member rotates the second support parts about a direction parallel to the second direction.

8. The curing device of claim 2, wherein at least one support part among the plurality of support parts is disposed between the first curing part and the second curing part when the curing unit is at the position corresponding to the substrate curing position.

9. The curing device of claim 1, wherein when viewed in the second direction, an area of the first curing part is greater than an area of a top surface of each of the plurality of substrates.

10. The curing device of claim 5, wherein when viewed in the first direction, an area of the second curing part is greater than an area of a first side surface or a second side surface of each of the plurality of substrates.

11. A curing device comprising:
a support frame including a substrate standby position, a substrate curing position, and a substrate unloading position;
a support unit disposed on the support frame, wherein the support unit includes a plurality of support parts spaced apart from each other in a first direction or a second direction crossing the first direction, and each of the plurality of support parts supports a bottom surface of a corresponding one of a plurality of substrates; and
a curing unit movable in the first direction, wherein the curing unit cures corresponding substrates on at least two of the plurality of support parts disposed at the substrate curing position, when the curing unit is at a position corresponding to the substrate curing position,
wherein the curing unit includes
a first curing part which, when viewed in the second direction, overlaps top surfaces of the corresponding substrates when the curing unit is at the position corresponding to the substrate curing position, and
a second curing part spaced apart from the first curing part, and overlapping, when viewed in the first direction, a side surface of a substrate of the corresponding substrates when the curing unit is at the position corresponding to the substrate curing position.

12. The curing device of claim 11, wherein when viewed in a third direction crossing the first direction and the second direction, the substrate standby position and the substrate unloading position are spaced more apart from the curing unit, than the substrate curing position,
the plurality of support parts comprise a first support part disposed at the substrate standby position, second support parts disposed at the substrate curing position, and a third support part disposed at the substrate unloading position, and
the curing unit cures the corresponding substrates on the second support parts.

13. The curing device of claim 12, wherein the curing unit further comprises a third curing part spaced apart from the first curing part with the second curing part therebetween, and
when viewed in the first direction and the curing unit is at the position corresponding to the substrate curing position, the third curing part overlaps a side surface of a substrate among the corresponding substrates.

14. The curing device of claim 13, wherein the support unit further comprises:
a first rotating member extending from the support frame in a third direction crossing the first direction and the second direction; and
a second rotating member disposed on the first rotating member, wherein the second rotating member rotates the plurality of support parts about a direction parallel to the second direction.

15. The curing device of claim 12, wherein the plurality of support parts moves while rotating about the second direction, as a rotation axis.

16. A method of manufacturing a display device, the method comprising:
preparing a support unit including a plurality of support parts disposed at a substrate standby position, a substrate curing position, and a substrate unloading position, and a curing unit spaced apart from the support unit and including a plurality of curing parts;
loading a substrate on a support part disposed at the substrate standby position among the plurality of support parts;
unloading a substrate on a support part disposed at the substrate unloading position among the plurality of support parts;
circulating the plurality of support parts in a way such that the support part disposed at the substrate standby position moves to the substrate curing position, one support part disposed at the substrate curing position among the plurality of support parts moves to the substrate unloading position, and another support part disposed at the substrate unloading position among the plurality of support parts moves to the substrate standby position;
performing a first movement in a way such that the curing unit moves to a position corresponding to the substrate curing position;
curing the substrate on the support part moved to the substrate curing position; and
performing a second movement in a way such that the curing unit is spaced apart from the position corresponding to the substrate curing position,
wherein the loading the substrate, the unloading the substrate, the circulating the plurality of support parts, the performing the first movement, the curing the substrate, and the performing the second movement are repeated.

17. The method of claim 16, wherein the substrate curing position is located between the substrate standby position and the curing unit, and
the substrate unloading position is spaced apart from the curing unit with the substrate curing position therebetween.

18. The method of claim 16, wherein at least two of the plurality of support parts are disposed at the substrate curing position,
in the circulating the support part, one support part among the at least two of the plurality of support parts disposed inside the substrate curing position moves to the substrate unloading position, and
another support part among the at least two of the plurality of support parts disposed inside the substrate curing position moves to a position adjacent to the substrate unloading position, inside the substrate curing position.

19. The method of claim 16, wherein the substrate curing position comprises a first curing position, and a second curing position spaced apart from the first curing position,
the curing unit comprises a first curing part which cures an upper part of the substrate, and a second curing part which cures a side part of the substrate,
in the circulating the support part, a support part disposed at the first curing position moves to the second curing position,
in the performing the first movement, the first curing part moves to a position corresponding to the first curing position, and the second curing part moves to a position corresponding to the second curing position, and
in the curing the substrate, the first curing part faces the upper part of the substrate when the substrate is located at the first curing position, and the second curing part faces the side part of the substrate when the substrate is located at the second curing position.

20. The method of claim 19, wherein the substrate curing position further comprises a third curing position spaced apart from the second curing position,
the curing unit further comprises a third curing part spaced apart from the second curing part, wherein the third curing part cures another side part of the substrate,
in the performing the first movement, the third curing part moves to a position corresponding to the third curing position,
when the substrate moves from the second curing position to the third curing position, the substrate rotates about a normal direction of the plurality of support parts, and
in the performing the first movement, the third curing part moves to a position corresponding to the third curing position.
